(19) United States
(12) Patent Application Publication
(10) Pub. No.: US 2012/0018193 A1
(43) Pub. Date: Jan. 26, 2012

(54) Multi layer circuit board and method of manufacturing the same

(75) Inventor: Ki Pyo Hong, Suwon (KR)

(73) Assignee: SAMSUNG ELECTRO-MECHANICS CO., LTD., Suwon (KR)

(21) Appl. No.: 13/064,971

(22) Filed: Apr. 28, 2011

(30) Foreign Application Priority Data
Jul. 21, 2010 (KR) 10-2010-0070515

(51) Int. Cl. H05K 1/02; B32B 38/04

(52) U.S. Cl. 174/251; 156/263

(57) ABSTRACT

There are provided a multi layer circuit board and a method of manufacturing the same. The multi layer circuit board includes each of ceramic boards having wiring patterns formed and stacked thereon; and via electrodes connecting in series the wiring patterns formed in the each of the ceramic boards, wherein one of the via electrodes is formed as a via group including a plurality of via units which connect in parallel one catch pad formed on one ceramic board and another catch pad formed on ceramic boards adjacent to the one ceramic board. Since the ceramic boards are connected through the plurality of via units, the reliability of the electrical connectivity of the via electrode may be improved, and the formation of a void and the protrusion of the via electrode may be prevented.

### CROSS-REFERENCE TO RELATED APPLICATIONS

This application claims the priority of Korean Patent Application No. 2010-0070515 filed on Jul. 21, 2010, in the Korean Intellectual Property Office, the disclosure of which is incorporated herein by reference.

### BACKGROUND OF THE INVENTION

1. Field of the Invention

The present invention relates to a multi layer circuit board and a method of manufacturing the same, and more particularly, to a multi layer circuit board having improved electrical characteristics by optimizing the structure of a via electrode and a method of manufacturing the same.

2. Description of the Related Art

In general, a multi layer circuit board is used as a component in combination with active elements, such as semiconductor IC chips and passive elements, such as capacitors, inductors and resisters, or is used as a simple semiconductor IC package. More particularly, the multi layer circuit board is widely used to constitute various electronic parts, such as Power Amplifier (PA) module substrates, Radio frequency (RF) diode switches, filters, chip antennas, various kinds of package parts, composite devices, or the like.

The structure of a conductive via is generally employed to make an electrical connection between layers in this multi layer circuit board.

As for the formation of a conductive via, a via electrode, is formed by providing a ceramic sheet which forms one layer of a multi layer circuit board, for example, a multi layer ceramic board, forming a through hole in a predetermined location of the ceramic sheet, and filling the through hole with a conductive material, such as silver or the like.

Moreover, in order to implement the electrical characteristics of individual products, several to several tens of wiring circuits, may be stacked in the ceramic sheet.

In this process of forming via electrodes, the conductive material in the via electrode may be protruded from the ceramic sheet due to a shrinkage difference between the via electrode and the ceramic sheet during the firing of the via electrode and the ceramic sheet, thereby causing a defect in a via. Furthermore, a void may occur between the via electrode and the ceramic sheet because of defective adhesion therebetween and interfere with the electrical connection of the via electrode.

Even when only one via electrode is defective, no remaining via in the ceramic sheet may be used.

Thus, a via electrode having an optimized structure, which is capable of solving the aforementioned defects in the related art is required.

### SUMMARY OF THE INVENTION

An aspect of the present invention provides a multi layer circuit board having high electrical connectivity between layers by preventing defects due to short circuits between the layers or short circuits between a wiring pattern and a via electrode.

An aspect of the present invention also provides a method of forming a via electrode used for the multi layer circuit.

According to an aspect of the present invention, there is provided a multi layer circuit board including a multi layer ceramic board including a plurality of ceramic layers stacked on top of one another and each having a wiring pattern formed thereon; and a plurality of via electrodes formed in the multi layer ceramic board and connecting the wiring patterns formed on different ceramic layers among the plurality of ceramic layers, wherein at least one of the plurality of via electrodes is a via group including a plurality of via units formed in parallel between the wiring patterns being connected

The via units in one of the ceramic layers may be arranged so as to alternate with the arrangement of via units in ceramic layers adjacent thereto.

The diameter of the via group may be 300 μm or less.

The diameter of via units may be 100 μm or less.

According to another aspect of the present invention, there is provided a method of manufacturing a multi layer circuit board, the method including: forming, in each of ceramic boards having wiring patterns formed thereon, vias forming via electrodes, wherein at least one of the vias is a via group including a plurality of via units; filing the via units with a conductive material; and stacking the ceramic boards in order that the wiring patterns formed on the different ceramic boards are connected by the via electrodes.

The via units in one of the ceramic boards may be arranged so as to alternate with the arrangement of via units in ceramic boards adjacent thereto.

The diameter of the via group may be 300 μm or less.

The diameter of via units may be 100 μm or less.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross sectional view illustrating a multi layer circuit board according to an exemplary embodiment of the present invention;

FIG. 2A is a top perspective view of a via electrode according to an exemplary embodiment of the present invention;

FIG. 2B is a perspective view illustrating a via electrode according to an exemplary embodiment of the present invention;

FIG. 3A is a top perspective view of a via electrode according to another exemplary embodiment of the present invention; and

FIG. 3B is a perspective view illustrating a via electrode according to another exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the dimension and the shape of components are exaggerated for clarity. Like reference numerals in the drawings denote like elements.

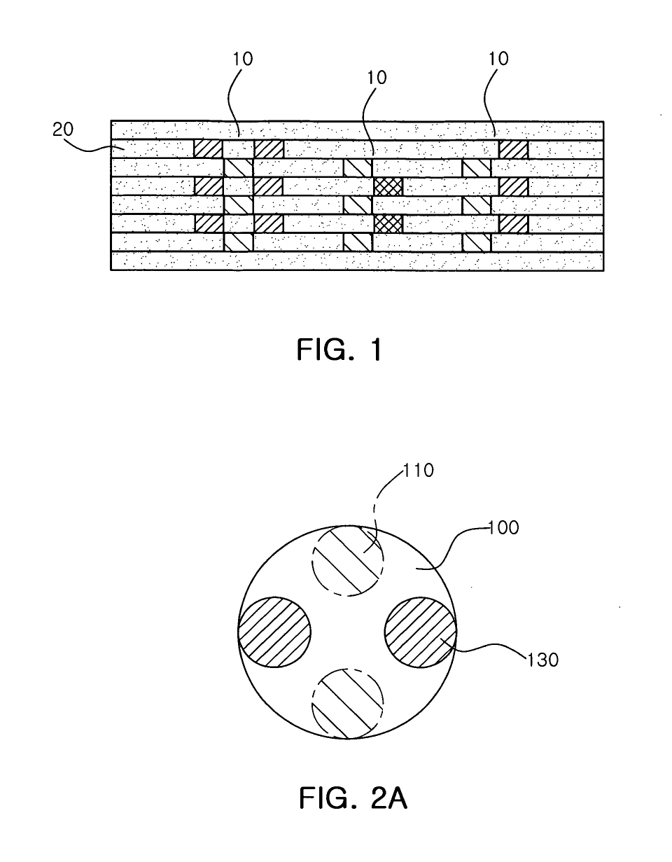

FIG. 1 is a cross sectional view illustrating a multi layer circuit board according to an exemplary embodiment of the present invention.

As illustrated in FIG. 1, a via electrode formed in a ceramic sheet 20 constituting a layer in a multi layer circuit board, for example, a multi layer ceramic board, is provided for electrically connecting the ceramic sheet 20 with the other ceramic sheets.

More particularly, a low temperature co-fired ceramic board may be used for the ceramic sheet 20, and in this case, the ceramic sheet 20 may include a glass, a binder, a ceramic filler, or the like. However, according to an embodiment of the present invention, a printed circuit board (PCB) or the like may be used instead of the ceramic sheet.

In this exemplary embodiment, the via electrode 10 has a maximum diameter of 200 μm and has a cylindrical or tapered shape. The via electrode is filled with a conductive material and electrically connects wiring patterns (e.g. catch pads) on the ceramic sheet 20, the wiring patterns being connected to the via electrode.

One catch pad formed on one ceramic sheet, the via electrode 10, and another catch pad formed on a ceramic sheet adjacent to the one ceramic sheet are sequentially connected in series.

In electrically connecting the one catch pad with the another catch pad, both catch pads are connected by the via electrode, namely, a via group according to an exemplary embodiment of the present invention.

The via group is configured to have a plurality of via units, such as two via units or three via units, and electrically connects the same catch pads.

In addition, the via group has a structure by which the plurality of via units are connected in parallel to the one catch pad and the another catch pad. That is, the via units have a structure by which the one catch pad and the another catch pad are electrically connected in parallel, and have an equivalent circuit structure to a circuit structure in which the one catch pad and the another catch pad are connected in series by a via electrode, namely, a via group, is provided.

In an exemplary embodiment of the present invention, the plurality of via units in one sheet are arranged to alternate with the arrangement of a plurality of via units in a sheet adjacent thereto, having one wiring pattern (hereinafter, referred as a ‘catch pattern’) therebetween. The catch pads are present on the upper and lower surfaces of a ceramic sheet in the ceramic board, and the catch pads are connected through the plurality of via units.

The via units disposed on the one sheet are symmetrically placed so as to have the maximum possible interval therebetween.

Since the height directional shrinkage of the via electrode is smaller than that of the ceramic board, the via electrode is less shrunken than the ceramic board, causing the via electrode to be protruded.

However, when the diameter of the via units is smaller, protruding of the via electrode caused by the shrinkage difference between the ceramic board and the via electrode during firing of the ceramic board and the via electrode may be prevented.

In an exemplary embodiment of the present invention, the catch pad may have a diameter of 300 μm or less. Moreover, the via unit may have a diameter of 100 μm or less.

The via electrode is not formed of a single via. The via electrode is formed of a via group including a plurality of via units. The diameter of via group is 100 μm or less. Thus, the diameter of the via units may be reduced.

In an exemplary embodiment of the present invention, since the diameter of the via units is relatively small, the amount of the conductive material protruded from the via electrode may be reduced.

Moreover, since the via units in one sheet are arranged so as to alternate with the arrangement of via units in sheets adjacent thereto, a longitudinal shrinkage difference between the ceramic board and the via electrode may be complemented.

Therefore, in an exemplary embodiment of the present invention, the protruding of the via electrode due to the shrinkage difference between the ceramic board and the via electrode may be effectively prevented.

In the case that any one of the plurality of via units in one sheet is defectively formed, thereby being electrically disconnected, the electrical connection of the via electrode may be maintained by the remainder of the via units.

Since the sheets are connected through the plurality of via units, the reliability of electrical connections in the ceramic board may be improved. Consequently, the connectivity of the ceramic board is improved, and the defect rate of parts used with the ceramic board may be reduced.

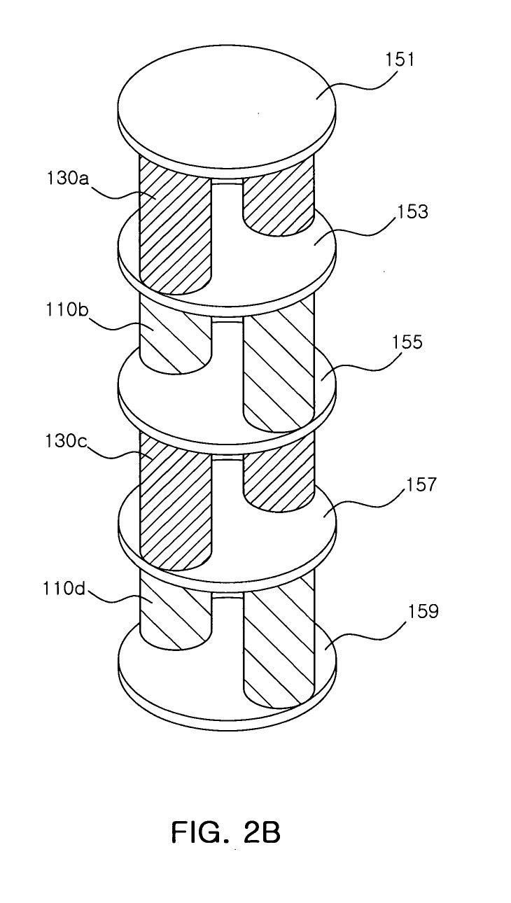

FIG. 2A is a top perspective view of a via electrode according to an exemplary embodiment of the present invention.

In the via electrode, two first via units 110 and two second via units 130 are alternately arranged, having a catch pad 100 therebetween.

The two first via units 110 are symmetrically disposed with relation to each other at an interval of 180 degree, and the two second via units 130 are symmetrically disposed to each other at an interval of 180 degree. The first via units 110 in one sheet are arranged so as to alternate with the arrangement of second via units 130 in sheets adjacent thereto. Since the two via units are disposed in each sheet, even in the case that any one of the two via units has a defective connection, the electrical connectivity of the via electrode may be maintained by the other via unit.

FIG. 2B is a perspective view illustrating a via electrode according to an exemplary embodiment of the present invention.

Referring to FIG. 2B, first to fifth catch pads 151, 153, 155, 157, and 159, each being disposed on an individual ceramic sheet; and a plurality of via units 130a, 110b, 130c, and 110d connecting each of the catch pads, respectively, are formed.

The two second via units 130a are formed between the first catch pad 151 and the second catch pad 153. The two second via units 130a form a via group to constitute a first via electrode, thereby electrically connecting the first catch pad 151 with the second catch pad 153.

Moreover, the two first via units 110b are formed between the second catch pad 153 and the third catch pad 155. The first via units 110b form a via group to constitute a second via electrode, thereby electrically connecting the second catch pad 153 and the third catch pad 155.

Likewise, the two second via units 130c are formed between the third catch pad 155 and the fourth catch pad 157. The second via units 130c form a via group to constitute a third via electrode, thereby electrically connecting the third catch pad 155 and the fourth catch pad 157.

Furthermore, the fourth catch pad 147 and the fifth catch pad 149 are electrically connected through a fourth via electrode which is formed of a via group.

The first via unit 110b and the second via units 130a and 130c are alternately arranged on each sheet, in order that protruding of the via electrode due to the longitudinal shrinkage difference between the ceramic board and the via electrode may be prevented.

Likewise, the second via unit 130c and the first via units 110b and 110d are alternately arranged on each sheet.

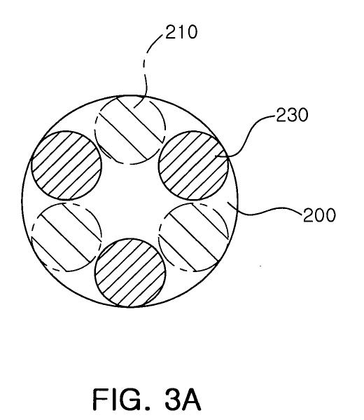

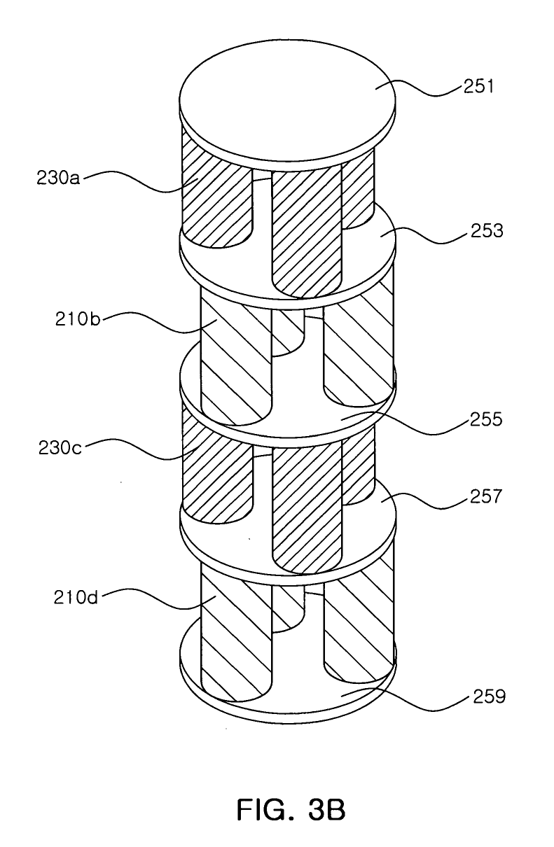

FIG. 3A is a top perspective view of a via electrode according to another exemplary embodiment of the present invention.

In the via electrode, three first via units 210 and three second via units 230 are alternately arranged, having a catch pad 200 therebetween.

The three first via units 210 are disposed to have intervals of 120 degrees therebetween, and three second via units 230 are disposed to have intervals of 120 degrees therebetween. The three first via units 210 in one sheet are arranged so as to alternate with the arrangement of three second via units 230 in sheets adjacent thereto. Since three via units are disposed in each sheet, even when any one of the three via units has a defective connection, the electrical connectivity of the via electrode may be maintained by the rest of the via units.

FIG. 3B is a perspective view illustrating a via electrode according to another exemplary embodiment of the present invention.

Referring to FIG. 3B, first to fifth catch pads 251, 253, 255, 257, and 259, each being disposed on an individual sheet; and a plurality of via units 230a, 210b, 230c, and 210d connecting each of the respective catch pads, are formed.

The three second via units 230a are formed between the first catch pad 251 and the second catch pad 253. The second via units 230a form a via electrode, thereby electrically connecting the first catch pad 251 with the second catch pad 253.

Moreover, the three first via units 210b are formed between the second catch pad 253 and the third catch pad 255. The first via units 210b constitute a via electrode, thereby electrically connecting the second catch pad 253 and the third catch pad 255.

Likewise, the three second via units 230c are formed between the third catch pad 255 and the fourth catch pad 257. The second via units 230c form a via electrode, thereby electrically connecting the third catch pad 255 and the fourth catch pad 257.

The first via unit 210b and the second via units 230a and 230c are alternately arranged on each sheet, in order that protruding of the via electrode due to the longitudinal shrinkage difference between the ceramic board and the via electrode may be prevented.

Likewise, the second via unit 230c and the first via units 210b and 210d are alternately arranged on each sheet.

In the above manner, the plurality of via units are disposed between the catch pads on the sheets. The via units form the via group to constitute the via electrode, by which the sheets are electrically connected.

In order to make a multi layer circuit board with via units according to an exemplary embodiment of the present invention, there is provided a circuit board made of an insulating material, for example, a low temperature co-fired ceramic board, such as a ceramic sheet. In this case, the ceramic sheet may include a glass, a binder, a ceramic filler, or the like. However, according to embodiments of the present invention, a PCB or the like may be used instead of the ceramic sheet.

According to an exemplary embodiment of the present invention, the via units are formed to have the maximum diameter of 100 μm by a laser beam or machinery. The via units in one sheet are arranged so as to alternate with the arrangement of via units in sheets adjacent thereto. The via units are symmetrically disposed at the maximum interval with regard to each catch pad.

Thereafter, the via units are filled with a material including Ag, Cu, Ni, or the like through a known process, such as screen printing. In addition, it is not necessarily required, but may be required to fill a through hole with a conductive material and planarize the surface of the through hole which is overfilled.

Then, an electrode pattern or a wiring pattern is printed on the circuit board filled with the conductive material. The via units may be connected on the wiring pattern and the wiring pattern may be the catch pad. The diameter of the wiring pattern may be 200 μm or less.

The circuit boards, each having the insulating patterns and the wiring patterns formed therein are stacked and compressed in order that the via units are connected in parallel, having each catch pad therebetween.

The multi layer board may be manufactured by a low temperature co-fired process, and such a laminated structure may be obtained by performing a co-fired process at a predetermined temperature.

The multi layer circuit board according to an exemplary embodiment of the present invention has a via electrode formed therein, and the via electrode is a via group including via units.

Therefore, the amount of the conductive material protruded from the via electrode of the present invention is reduced compared to that of a via electrode in which a single via hole is formed.

In addition, since the via group in one sheet is arranged so as to alternate with the arrangement of the via group in sheets adjacent thereto, a gap between sheets due to the longitudinal shrinkage difference between the ceramic board and the via electrode may be complemented, thereby allowing the formation of a void and the protrusion of a conductive material to be prevented.

As set forth above, according to exemplary embodiments of the invention, the multi layer circuit board having a higher electrical connectivity between micro-sized via electrodes by preventing defects due to short circuits between the layers or short circuits between a wiring pattern and a via electrode, may be provided.

While the present invention has been shown and described in connection with the exemplary embodiments, it will be apparent to those skilled in the art that modifications and variations can be made without departing from the spirit and scope of the invention as defined by the appended claims.

What is claimed is:

1. A multi layer circuit board comprising:
a multi layer ceramic board including a plurality of ceramic layers stacked on top of one another and each having a wiring pattern formed thereon; and
a plurality of via electrodes formed in the multi layer ceramic board and connecting the wiring patterns formed on different ceramic layers among the plurality of ceramic layers, wherein at least one of the plurality of via electrodes is a via group including a plurality of via units formed in parallel between the wiring patterns being connected.

2. The multi layer circuit board of claim 1, wherein the via units in one of the ceramic layers are arranged so as to alternate with the via units in ceramic layers adjacent thereto.

3. The multi layer circuit board of claim 1, wherein the diameter of the via group is 300 μm or less.

4. The multi layer circuit board of claim 1, wherein the diameter of via units is 100 μm or less.

5. A method of manufacturing a multi layer circuit board, the method comprising:
forming, in each of ceramic boards having wiring patterns formed thereon, vias forming via electrodes, wherein at least one of the vias is a via group including a plurality of via units;
filing the plurality of via units with a conductive material and forming a plurality of via electrode; and
stacking the ceramic boards in order that the wiring patterns formed on different ceramic boards are connected by the via electrodes.

6. The method of claim 5, wherein the via units in one of the ceramic boards are arranged so as to alternate with the arrangement of via units in ceramic boards adjacent thereto.

7. The method of claim 5, wherein the diameter of the via group is 300 μm or less.

8. The method of claim 5, wherein the diameter of via units is 100 μm or less.
